(19) United States
(12) Patent Application Publication
(10) Pub. No.: US 2024/0162396 A1
(43) Pub. Date: May 16, 2024

(54) LIGHT-EMITTING PACKAGE AND LIGHT-EMITTING MODULE

(71) Applicant: LITE-ON TECHNOLOGY CORPORATION, TAIPEI CITY (TW)

(72) Inventors: CHENG-HONG SU, Taipei City (TW); CHIH-LI YU, New Taipei City (TW); CHENG-HAN WANG, New Taipei City (TW)

(21) Appl. No.: 18/509,229

(22) Filed: Nov. 14, 2023

Related U.S. Application Data
(60) Provisional application No. 63/425,732, filed on Nov. 16, 2022.

(30) Foreign Application Priority Data
Apr. 10, 2023 (CN) 202310372454.0

(51) Int. Cl. H01L 33/58

(52) U.S. Cl. CPC H01L 33/58

(57) ABSTRACT

A light-emitting package includes a light-transmitting carrier and a light-emitting element. The light-transmitting carrier has a carrying surface, and the light-transmitting carrier contains a base resin and a first phosphorescent powder. The light-emitting element is disposed on the carrying surface. A light-emitting module that contains a phosphorescent powder is also provided.

### CROSS-REFERENCE TO RELATED PATENT APPLICATION

This application claims the benefit of priorities to the U.S. Provisional Patent Application Ser. No. 63/425,732, filed on Nov. 16, 2022, and China Patent Application No. 202310372454.0, filed on Apr. 10, 2023, in the People's Republic of China. The entire content of each of the above identified applications is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a light-emitting field, and more particularly to a light-emitting package containing a phosphorescent powder and a light-emitting module thereof

### BACKGROUND OF THE DISCLOSURE

In the related art, a conventional light-emitting module converts the received electrical energy into light energy and heat energy. Once the power is cut off, the light-emitting module cannot emit light. In order for the light-emitting module to continue emitting light, electrical energy needs to be continuously supplied, which is not conducive to energy saving.

Therefore, how to enable the light-emitting module to have a light-storage function, maintain a certain luminous brightness, and achieve energy-saving effects through improvements in structural design, so as to overcome the above-mentioned problems, has become one of the important issues to be solved in this technical field.

### SUMMARY OF THE DISCLOSURE

In response to the above-referenced technical inadequacies, the present disclosure provides a light-emitting package and a light-emitting module. By using a phosphorescent powder, the light-emitting package can continue emitting phosphorescence after power is cut off Specifically, the phosphorescent powder absorbs a light wavelength (ranging, for example but not limited to, from 400 nm to 460 nm) of the light-emitting package until the phosphorescent powder is capable of emitting bright light and obtains the ability to store light. In this way, a glowing time of the light-emitting module can be extended, and the brightness of the light can be maintained.

In order to solve the above-mentioned problems, one of the technical aspects adopted by the present disclosure is to provide a light-emitting package, which includes a light-transmitting carrier and a light-emitting element. The light-transmitting carrier has a carrying surface, and the light-transmitting carrier contains a base resin and a first phosphorescent powder. The light-emitting element is arranged on the carrying surface.

In one of the possible or preferred embodiments, the light-transmitting carrier includes a cavity, and the carrying surface is located at the bottom of the cavity.

In one of the possible or preferred embodiments, the total weight of the base resin is 100 parts by weight, and the content of the first phosphorescent powder is 20-50 parts by weight.

In one of the possible or preferred embodiments, the light-emitting package further includes a light-transmitting gel covering the light-emitting element.

In one of the possible or preferred embodiments, the light-transmitting gel contains a second phosphorescent powder.

In one of the possible or preferred embodiments, the weight of the base resin is 100 parts by weight, and the content of the second phosphorescent powder is 20-40 parts by weight.

In one of the possible or preferred embodiments, the light-transmitting gel contains fluorescent powder.

In one of the possible or preferred embodiments, the first phosphorescent powder is evenly distributed in the base resin.

In one of the possible or preferred embodiments, the light-emitting package further includes a microcontroller and an ambient light sensor. The microcontroller is electrically connected to the light-emitting element. The ambient light sensor is electrically connected to the microcontroller. The ambient light sensor senses a quantity of light in the external environment, and correspondingly transmits a plurality of light sensing signals to the microcontroller. When the microcontroller determines that a light quantity of the light-sensing signals is lower than the preset light quantity, the microcontroller sequentially transmits power-on signals and power-off signals to the light-emitting element within one cycle, driving the light-emitting element to emit light and stop emitting light accordingly.

In order to solve the above-mentioned problems, another one of the technical aspects adopted by the present disclosure is to provide a light-emitting module, which includes an accommodating housing, a light guide column, and a light-emitting package. The accommodating housing has one end surface forming a first opening and another end surface forming a second opening, and a channel extends from the first opening to the second opening. The light guide column contains a phosphorescent powder. The light guide column is formed in the channel by an insert molding and integrated with the accommodation housing. The light guide column has a light emitting portion and a light incident portion, the light emitting portion exposes at the first opening, and the light incident portion is adjacent to the second opening. The light-emitting package is combined with the accommodation housing. The light-emitting package has a light-emitting surface facing to the light incident portion so that a light emitted by the light-emitting package enters through the light incident portion and is emitted from the light emitting portion.

In one of the possible or preferred embodiments, the total weight of the light guide column is 100 parts by weight, and the content of the phosphorescent powder is 20-50 parts by weight.

In one of the possible or preferred embodiments, the light-emitting element includes a light-transmitting carrier and a light-emitting chip. The light-emitting chip is located in the light-transmitting carrier. The light-transmitting carrier contains a plurality of phosphorescent powders.

Therefore, in the light-emitting package provided by the present disclosure, by virtue of “the light-transmitting carrier containing a base resin and a first phosphorescent powder,” the light-emitting package can stimulate the phosphorescent powder to produce a light energy storing effect, so as to prolong a light-emitting time of the light-emitting package, reduce a usage amount of electrical energy, and achieve energy saving.

Furthermore, in the light-emitting package provided by the present disclosure, by virtue of “in response to the microcontroller determining that the light quantity of one of the light-sensing signals being lower than a preset light quantity, the microcontroller sequentially transmits power-on signals and power-off signals to the light-emitting element within one cycle, so as to drive the light-emitting element to correspondingly emit light or stop emitting the light,” the light-emitting package can continuously emit light and save the electrical energy.

Furthermore, in the light-emitting module provided by the present disclosure, by virtue of “a light guide column containing a phosphorescent powder,” the light incident portion of the light guide column receives the light emitted by the light-emitting package, and stimulates the phosphorescent powder to emit light autonomously. When no power is supplied, the light guide column can slow down the fading of the light due to the light energy storing effect of the phosphorescent powder, thereby saving electrical energy and achieving efficient light emission.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a light emitting package according to one embodiment of the present disclosure;

FIG. 2 is a schematic exploded view of the embodiment shown in FIG. 1;

FIG. 3 is a schematic structural diagram of a light emitting package according to one embodiment of the present disclosure;

FIG. 4 is a schematic view of a light-emitting module according to one embodiment of the present disclosure;

FIG. 5 is a schematic exploded view of the embodiment shown in FIG. 4;

FIG. 6 is a cross-sectional view of the embodiment shown in FIG. 4; and

FIG. 7 is a schematic view of a traffic signal according to one embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

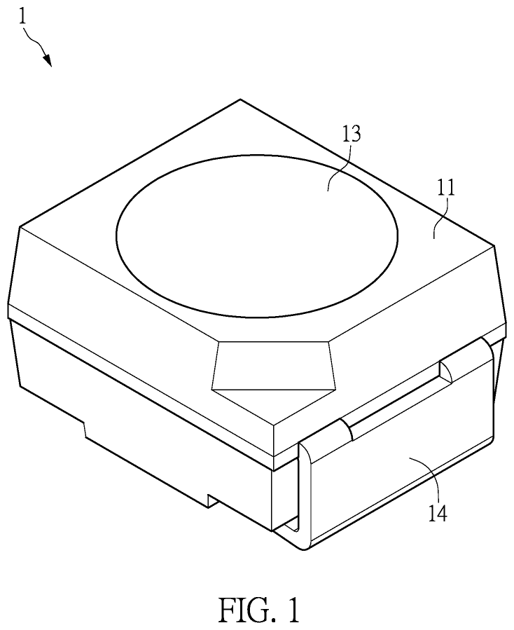

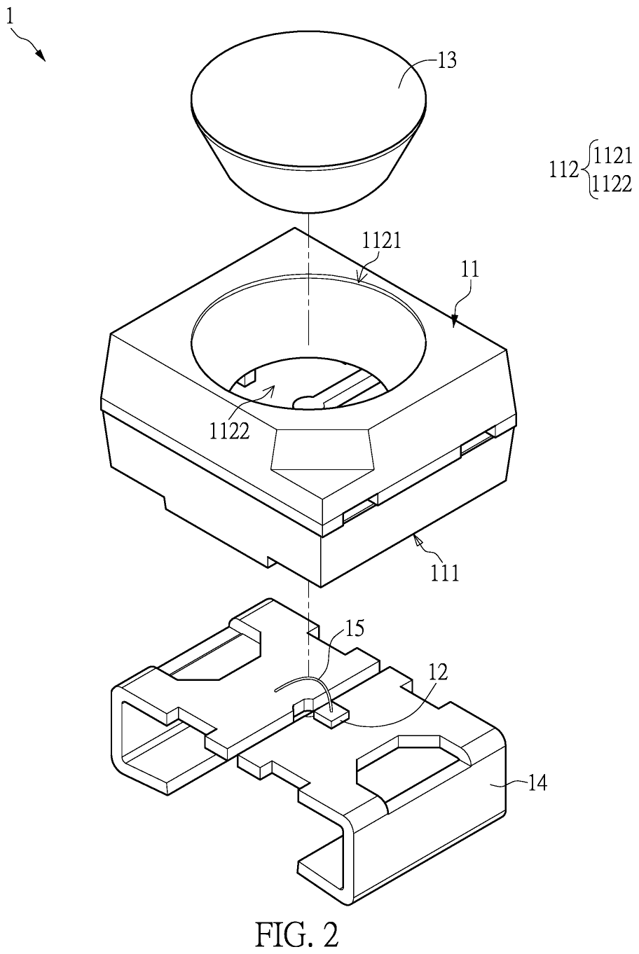

Referring to FIG. 1 and FIG. 2, FIG. 1 is a schematic view of a light emitting package according to one embodiment of the present disclosure, and FIG. 2 is a schematic exploded view of the embodiment shown in FIG. 1. One embodiment of the present disclosure provides a light-emitting package 1. The light-emitting package 1 includes a light-transmitting carrier 11 and a light-emitting element 12. The light-transmitting carrier 11 has a carrying surface 111, and the light-transmitting carrier 11 contains a base resin and a first phosphorescent powder. The light-emitting element 12 is disposed on the carrying surface 111. The light-emitting element 12 can be, for example, a light-emitting diode (LED). However, the present disclosure is not limited thereto. According to some embodiments, the material of the base resin may be a phenolic resin, an epoxy resin, an acrylic resin, a bismaleimide triazine (BT) resin, a polyphthalamide (PPA), a liquid crystal polymer (LCP) resin, a silicone resin, a urea resin, and other resins, but is not limited thereto. In some embodiments, the material of the base resin can also be polyamide 9T (PA9T) or LCP plastic. In the present embodiment, the base resin is a polyamide resin. The first phosphorescent powder can be, for example, strontium trialuminate (SrAl₂O₄:Eu, Dy, having an emission wavelength of 520 nm), Sr₄Al₁₄O₂₅:Eu, Dy (having an emission wavelength of 500 nm), CaS:Eu, Tm (having an emission color of red), ZnS:Cu, Mn, Co (having an emission color of yellow-orange), ZnS:Cu (having an emission color of yellow-green), and (Ca,Sr)S:Bi (having an emission color of blue-purple). In the present embodiment, the material of the first phosphorescent powder is SrAl₂O₄:Eu, Dy. In some embodiments, the base resin can be doped with an anti-settling agent, so that the first phosphorescent powder can be uniformly distributed in the base resin.

As shown in FIG. 2, the light-transmitting carrier 11 includes a cavity 112, and the carrying surface 111 is located at the bottom of the cavity 112. The cavity 112 has a light exit hole 1121 and a light entrance hole 1122 that is opposite to the light exit hole 1121. In the present embodiment, the light-emitting element 12 is located in the light entrance hole 1122, and the light emitted by the light-emitting element 12 is emitted from the light exit hole 1121. In the embodiment shown in FIG. 2, the light-emitting package 1 further includes a light-transmitting gel 13 covering the light-emitting element 12, and the light-transmitting gel 13 is filled in the cavity 112. The light-emitting package 1 further includes a carrying base 14, which carries the light-transmitting carrier 11. The carrying base 14 is made of a conductive material, such as metal materials, but is not limited thereto. The light-emitting element 12 is disposed on the carrying base 14, and is electrically connected to the carrying base 14 through a conductive wire 15.

In some embodiments, based on a total weight of the base resin in the light-emitting package 1 being 100 parts by weight, a content of the first phosphorescent powder is 20-50 parts by weight. In some embodiments, in the process of manufacturing the light-transmitting carrier 11, based on the total weight of the base resin being 100 parts by weight, the light-transmitting carrier 11 further contains 2 parts by weight of the anti-settling agent.

According to some embodiments, the light-transmitting gel 13 contains a second phosphorescent powder. Material selection of the second phosphorescent powder is the same as that of the first phosphorescent powder. The second phosphorescent powder can have a different color from the first phosphorescent powder. In this way, the light-emitting package 1 can have a color change after a power is turned off. According to some embodiments, in the light-emitting package 1, based on a total weight of the base resin being 100 parts by weight, a content of the second phosphorescent powder is 20-40 parts by weight. In other embodiments, the light-transmitting gel 13 contains a fluorescent powder. The fluorescent powder can also be stimulated by the light emitted by the light-emitting element 12, so as to emit light autonomously. When the light-emitting package 1 is powered on, the fluorescent powder can absorb and convert part of the light emitted by the light-emitting element 12, such that a mixed light is produced. The color of the mixed light is different from the light emitted by the light-emitting element 12. In some embodiments, the light-transmitting gel 13 may simultaneously contain the second phosphorescent powder and a fluorescent powder. The light-transmitting gel 13 can emit light when the light-emitting package 1 is powered on or when the power is turned off.

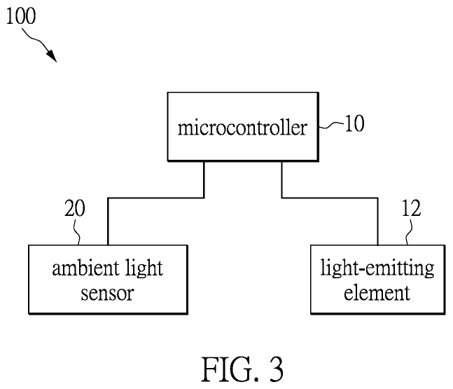

Reference is made to FIG. 3, which is a schematic structural diagram of a light emitting package 100 according to one embodiment of the present disclosure. The light emitting package 100 further includes a microcontroller 10 and an ambient light sensor 20. The ambient light sensor 20 is electrically connected to the microcontroller 10. The light-emitting element 12 is electrically connected to the microcontroller 10. The ambient light sensor 20 senses a quantity of light in the external environment, and correspondingly transmits a plurality of light sensing signals to the microcontroller 10. When the microcontroller 10 determines that one light quantity of the light-sensing signals is lower than the preset light quantity, the microcontroller 10 sequentially transmits power-on signals and power-off signals to the light-emitting element 12 within one cycle, driving the light-emitting element 12 to emit light and stop emitting light accordingly. According to this configuration, when the light quantity of the light-sensing signal detected by the ambient light sensor 20 is less than the preset light quantity (depending on the setting of a user), the microcontroller 10 transmits the power-on signal to drive the light-emitting element 12 to emit light, and transmits the power-off signal within a certain period of time to stop the light-emitting element 12 from emitting the light.

The light-emitting element 12 contains the phosphorescent powder, and the phosphorescent powder receives a light wavelength emitted by the light-emitting element 12, such that the phosphorescent powder is stimulated to emit light, and maintains the light for a period of time. Afterwards, when the light quantity of the light-sensing signal is lower than the preset light quantity, the microcontroller 10 once again transmits the power-on signal and the power-off signal to the light-emitting element 12, so as to drive the light-emitting element 12 to emit light and stop emitting the light. Such a process is repeated. In this way, the power-on time of the light-emitting element 12 can be significantly reduced, and electrical energy can be saved.

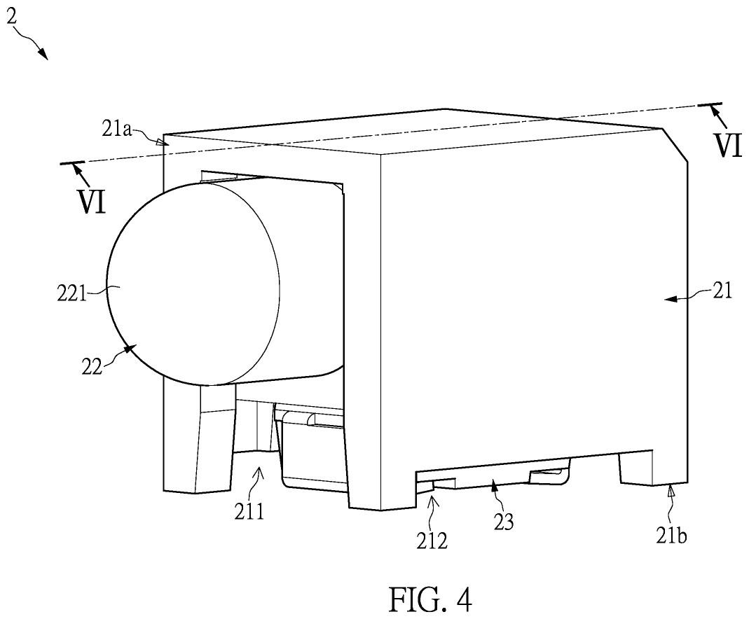

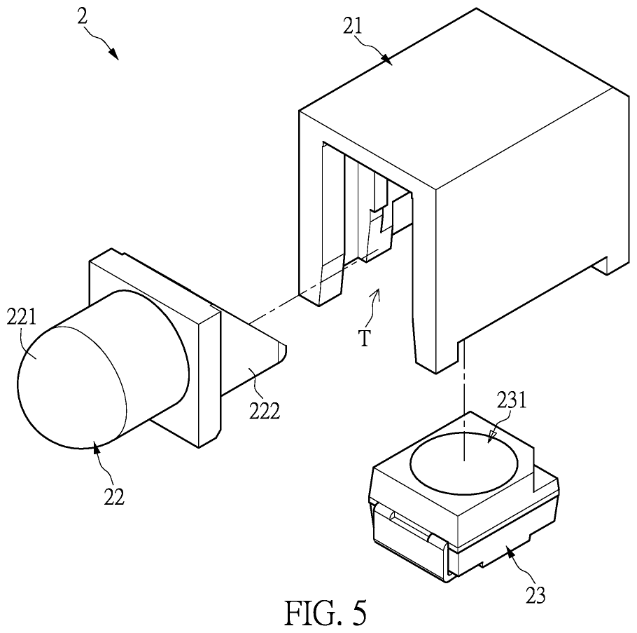

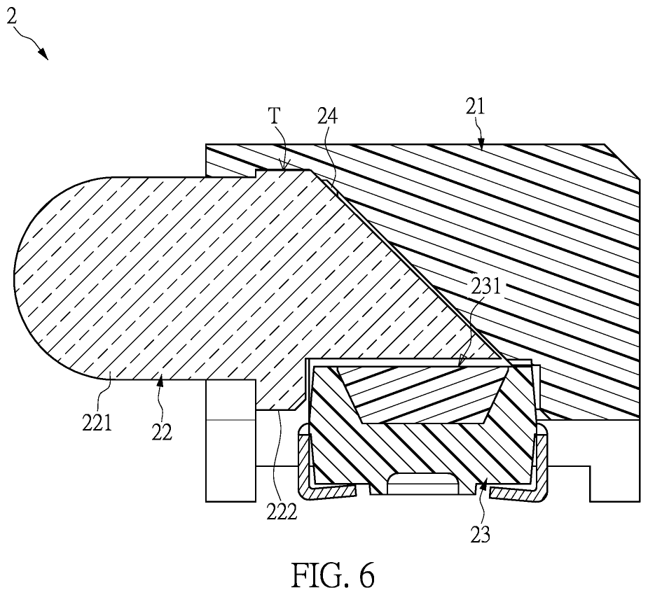

Referring to FIG. 4 to FIG. 6, FIG. 4 is a schematic view of a light-emitting module according to one embodiment of the present disclosure, FIG. 5 is a schematic exploded view of the embodiment shown in FIG. 4, and FIG. 6 is a cross-sectional view of the embodiment shown in FIG. 4.

A light-emitting module 2 includes an accommodating housing 21, a light guide column 22, and a light-emitting package 23. The accommodating housing 21 has one end surface 21a that forms a first opening 211, another end surface 21b that forms a second opening 212, and a channel T that extends from the first opening 211 to the second opening 212; wherein the first opening 211 is in spatial communication with the second opening 212. The light guide column 22 containing a phosphorescent powder, wherein the light guide column 22 is formed in the channel T by insert molding, and is integrally formed with the accommodation housing 21; wherein the light guide column 22 includes a light emitting portion 221 and a light incident portion 222, the light emitting portion 221 is exposed from the first opening 211, and the light incident portion 222 is adjacent to the second opening 212. The light-emitting package 23 is combined with the accommodation housing 21; wherein the light-emitting package 23 has a light-emitting surface 231 that faces toward the light incident portion 222 of the light guide column 22, so that light emitted by the light-emitting package 23 enters through the light incident portion 222 of the light guide column 22 and is emitted from the light emitting portion 221 of the light guide column 22.

The light-emitting package 23 can be a general light-emitting package that does not contain any phosphorescent powder, but can also be the above-mentioned light-emitting package 1. However, there is no limitation in the present disclosure. The channel T can be linear or have a curved shape. In the embodiment shown in FIG. 6, the channel T is substantially in an “L” shape. A bend of the channel T is a reflective portion that corresponds to a reflective structure 24, such as a reflective sheet or a reflective plate. The reflective structure 24 can be disposed on an inner wall surface of the channel T or at a portion corresponding to the bend in the light guide column 22. In some embodiments, the reflective sheet or plate can be disposed at a position that corresponds to the bend of the channel T and is between the light guide column 22 and the inner wall surface of the channel T. However, the present disclosure is not limited thereto. Based on the structure of the channel T and the design of the light guide column 22, a light emitting direction of the light-emitting package 23 can be different from an actual emission direction of the light exit portion 221 of the light guide column 22. According to some embodiments, the total weight of the light guide column 22 of the light-emitting module 2 is 100 parts by weight, and the content of the phosphorescent powder is 20-50 parts by weight.

The light-emitting package 23 and the light-emitting module 2 of the present disclosure can be used in fields such as signboards, advertising boards, warning signs, decorations, watches, and clothing However, the present disclosure is not limited thereto.

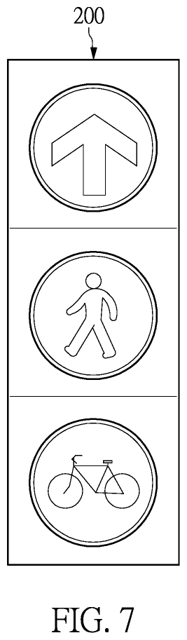

Referring to FIG. 7, FIG. 7 is a schematic diagram of a traffic signal according to an embodiment of the present disclosure. A traffic signal 200 uses the light-emitting package 23 or the light-emitting module 2 according to one embodiment of the present disclosure. The light-emitting element 12 contains the phosphorescent powder, and the phosphorescent powder receives a light wavelength emitted by the light-emitting element 12, such that the phosphorescent powder is stimulated to emit light, and maintains the light for a period of time. Afterwards, when the light quantity of the light-sensing signal is lower than the preset light quantity, the microcontroller 10 once again transmits the power-on signal and the power-off signal to the light-emitting element 12, so as to drive the light-emitting element 12 to emit light and stop emitting the light. Such a process is repeated. In this embodiment, when the ambient light is darker, the microcontroller 10 (as shown in FIG. 3) transmits the power-on signal and the power-off signal for a longer period. In other words, when the ambient light is darker, the time between the light-emitting element 12 emitting the light and stopping emission of the light is longer. Accordingly, the traffic signal 200 may consume a smaller amount of electrical energy at night, thereby achieving energy saving.

### BENEFICIAL EFFECTS OF THE EMBODIMENTS

In conclusion, according to one embodiment of the light-emitting package provided by the present disclosure, by virtue of “the light-transmitting carrier containing a base resin and a first phosphorescent powder,” the light-emitting package can stimulate the phosphorescent powder to produce a light energy storing effect, so as to prolong a light-emitting time of the light-emitting package, reducing a usage amount of electrical energy, and achieve energy saving.

According to one embodiment of the present disclosure, the light-emitting package further includes the light-transmitting gel, and the light-transmitting gel contains the second phosphorescent powder, such that the light-emitting time of the light-emitting package can be further prolonged and the electrical energy can be further saved.

Furthermore, in the light-emitting package provided by the present disclosure, by virtue of “in response to the microcontroller determining that the light quantity of one of the light-sensing signals being lower than a preset light quantity, the microcontroller sequentially transmits power-on signals and power-off signals to the light-emitting element within one cycle, so as to drive the light-emitting element to correspondingly emit light or stop emitting the light,” the light-emitting package can continuously emit light and save the electrical energy.

Furthermore, in the light-emitting module provided by the present disclosure, by virtue of “a light guide column containing a phosphorescent powder,” the light incident portion of the light guide column receives the light emitted by the light-emitting package, and stimulates the phosphorescent powder to emit light autonomously. When no power is supplied, the light guide column can slow down the fading of the light due to the light energy storing effect of the phosphorescent powder, thereby saving electrical energy and achieving efficient light emission. According to one embodiment of the present disclosure, the channel has a bend, and a direction by which the light incident portion receives the light is different from a direction by which the light emitting portion emits the light. In this way, application of the light-emitting module of the present disclosure can be more extensive.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A light-emitting package, comprising:
a light-transmitting carrier having a carrying surface, wherein the light-transmitting carrier contains a base resin and a first phosphorescent powder; and
a light-emitting element disposed on the carrying surface.

2. The light-emitting package according to claim 1, wherein the light-transmitting carrier includes a cavity, and the carrying surface is located at a bottom of the cavity.

3. The light-emitting package according to claim 1, wherein, based on a total weight of the base resin being 100 parts by weight, a content of the first phosphorescent powder is between 20 parts by weight and 50 parts by weight.

4. The light-emitting package according to claim 1, wherein the light-emitting package further includes a light-transmitting gel that covers the light-emitting element.

5. The light-emitting package according to claim 4, wherein the light-transmitting gel contains a second phosphorescent powder.

6. The light-emitting package according to claim 5, wherein, based on a total weight of the base resin being 100 parts by weight, a content of the second phosphorescent powder is between 20 parts by weight and 40 parts by weight.

7. The light-emitting package according to claim 4, wherein the light-transmitting gel contains a fluorescent powder.

8. The light-emitting package according to claim 1, wherein the first phosphorescent powder is evenly distributed in the base resin.

9. The light-emitting package according to claim 1, further comprising:
a microcontroller electrically connected to the light-emitting element; and
an ambient light sensor electrically connected to the microcontroller;
wherein the ambient light sensor senses a light quantity of an external environment, and correspondingly transmits a plurality of light-sensing signals to the microcontroller; wherein, when the microcontroller determines that the light quantity of one of the light-sensing signals is lower than a preset light quantity, the microcontroller sequentially transmits power-on signals and power-off signals to the light-emitting element within one cycle, so as to drive the light-emitting element to correspondingly emit light or stop emitting the light.

10. A light-emitting module, comprising:
an accommodating housing, wherein the accommodating housing has one end surface that forms a first opening, another end surface that forms a second opening, and a channel that extends from the first opening to the second opening; wherein the first opening is in spatial communication with the second opening;
a light guide column containing a phosphorescent powder, wherein the light guide column is formed in the channel by insert molding, and is integrally formed with the accommodation housing; wherein the light guide column includes a light emitting portion and a light incident portion, the light emitting portion is exposed from the first opening, and the light incident portion is adjacent to the second opening; and
a light-emitting package, wherein the light-emitting package is combined with the accommodation housing; wherein the light-emitting package has a light-emitting surface that faces toward the light incident portion of the light guide column, so that light emitted by the light-emitting package enters through the light incident portion of the light guide column and is emitted from the light emitting portion of the light guide column.

11. The light-emitting module according to claim 10, wherein, based on a total weight of the light guide column being 100 parts by weight, a content of the phosphorescent powder is between 20 parts by weight and 50 parts by weight.
